(19) United States
(12) Patent Application Publication
(10) Pub. No.: US 2005/0259777 A1
(43) Pub. Date: Nov. 24, 2005

(54) Method for expanding the addressing capability of a plurality of registers and apparatus for implementation thereof

(76) Inventor: George Claseman, Campbell, CA (US)

Correspondence Address: Dorsey & Whitney LLP;Intellectual Property Department, Suite 3400, Four Embarcadero Center, San Francisco, CA, 94111-4187, US

(21) Appl. No.: 10/849,749

(22) Filed: May 19, 2004

(51) Int. Cl. G11C 19/00

(52) U.S. Cl. 377/64

(57) ABSTRACT

A microprocessor includes a plurality of blocks of registers, each block of registers having at least two registers. The microprocessor further includes a location register for selectively characterizing at least one of the blocks as a specified block of registers, and a control register for selecting at least one operation for the indicated block of registers. In one example of the invention, the control and location registers are two of the registers specified by the IEEE 802.3 standard.

### TECHNICAL FIELD

The present invention relates to register addressing, and more particularly, to expanded register addressing.

### BACKGROUND OF THE INVENTION

IEEE 802 standards provide for data communication technology over local area networks (LANs). In particular IEEE standard 802.3 specifies a management interface between a Media Access Control (MAC) sublayer and a physical layer. In IEEE 802.3 clause 22, thirty-two 16-bit registers are specified per each physical port for direct addressing by the standard. The standard itself specifies the use of 16 of these 32 16-bit registers, leaving 16 registers for specification by individual vendors or users of the standard.

Other standards and communication environments similarly limit the number of available registers for unrestricted use.

It has been found that there is a need for a system and method of expanding the addressing capability of a fixed number of registers.

### SUMMARY OF THE INVENTION

In accordance with a first aspect of the present invention, a control engine is in communication with a plurality of blocks of registers, each block of registers having at least two registers. The control engine is further in communication with a location register for selectively characterizing at least one of the blocks as a specified block of registers, and a control register for selecting at least one operation for the indicated block of registers and specifying at least one port of the indicated block of registers. In one example of the invention, the control and location registers are two of the registers specified by the IEEE 802.3 standard.

In accordance with a second aspect of the present invention, the addressing capability of a plurality of registers in a microprocessor is expanded. At least two of the plurality of registers are designated as a block of registers. A plurality of such blocks of registers are provided. A first register within the plurality of registers that is separate from the blocks of registers is designated as a location register for selectively characterizing at least one of such blocks of registers as an indicated block of registers. A second register within the plurality of registers that is separate from the blocks of registers is designated as a control register for specifying at least one operation for the indicated block of registers.

### BRIEF DESCRIPTION OF THE DRAWINGS

FIG. 1 is a schematic representation of registers defined by the IEEE 802.3 standard, according to an embodiment of the present invention.

FIG. 2 is a schematic representation of the 16 vendor-specified registers in FIG. 1, according to an embodiment of the present invention.

FIG. 3 is a schematic representation of the control and location registers in FIG. 2, according to an embodiment of the present invention.

### DETAILED DESCRIPTION OF PREFERRED EMBODIMENTS

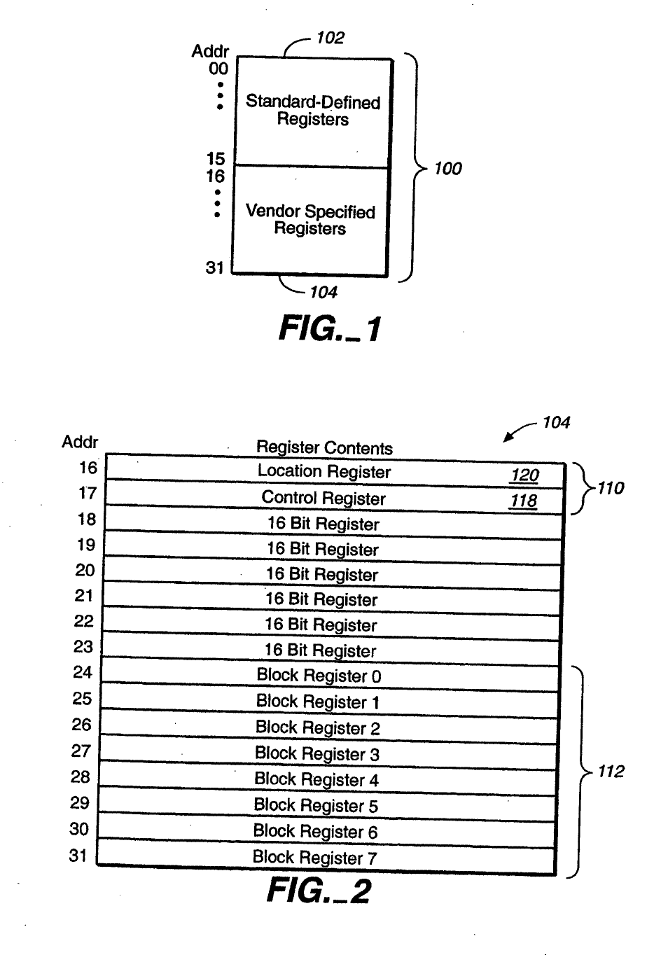

Clause 22 of the IEEE 802.3 standard specifies 32 registers, half of which are defined by the standard. FIG. 1 illustrates the thirty-two specified registers 100, having addresses 00-31. Registers 102 having addresses 00-15 are defined by the standard. Accordingly, sixteen registers 104 remain for vendor-specific definition. Each of the IEEE 802.3 clause 22 registers is directly addressed by the standard, as a five-bit address. The thirty-two registers 100 shown in FIG. 1 are in communication with a control engine of a networked device. The control engine generally receives instructions destined for the registers and accesses the registers using methods described herein. The control engine may be implemented in hardware, software, or a combination thereof. For example, the control engine may be implemented in the physical layer of a networked device. The control engine may also include a microprocessor. Generally, each networked port in communication according to the IEEE 802.3 standard has a designated thirty-two registers as shown in FIG. 1.

Address expansion allows access to a larger space beyond the thirty-two registers shown in FIG. 1, as well as added control, status, and management, while maintaining the ability to interface in communication with other devices according to the IEEE 802.3 standard. It will be appreciated that, while the address expansion schemes described herein find particular use in conjunction with the IEEE 802.3 standard, other analogous situations and standard communication protocols exist specifying access to a finite number of registers that would similarly benefit from the address expansion techniques described herein. Accordingly, the invention is not limited to implementation with the IEEE 802.3 standard.

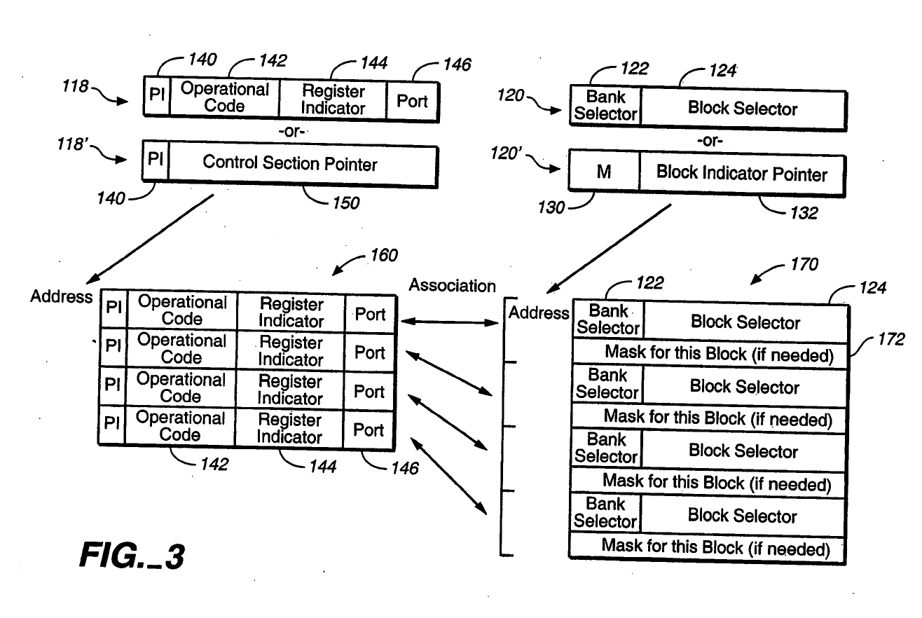

Two of the sixteen registers 104 are designated as control and location registers 110, shown in FIG. 2. A block of eight registers, as exemplified in FIG. 2 by the last eight registers 112 of the sixteen, are treated as a single register block. As shown in FIG. 2, for ease of addressing the control and location registers are at locations 16 and 17 while the block of eight registers are at locations 24-31. While this configuration provides some addressing conveniences, the registers 110 and 112 may be located at any available position. Registers at locations 18 through 23 are fixed address vendor specific registers. In the embodiment shown, these registers do not change when the location register is changed. The location register indicates which eight register block 112 is being pointed to. The control register 118 and location register 120 each contain either direct control or a pointer to control information in another register. FIG. 3 depicts these embodiments of the control register 118 and the location register 120.

The location register 120, shown as 120 and 120′ in FIG. 3, can contain either a direct block indicator, or a pointer to block indicator information. The location register 120 contains a direct block indicator and has two sections, a bank selector 122 and a block selector 124. The bank selector 122 indicates which bank of registers are being addressed, and the block selector 124 indicates the block of registers being accessed in register locations 24 through 31 (112). In a preferred embodiment, the bank selector 122 is three bits long and the remaining 13 bits of the 16-bit register are used for the block selector 124. With eight registers per block, and 13 address bits, this allows up to 65,000 registers per bank. In a preferred embodiment, bank 0 contains the IEEE 802.3 clause 22 registers as the first 32 locations. Banks 1 through 7 can be used for other registers, not shown in FIGS. 1 and 2, and may also be shared space accessible across many or all ports of the communication scheme. The banks allow access to additional register sets which could be unique to each port, or could be shared across ports. This allows up to 2³*2¹³*2^{3=524,000} registers per port.

The location register 120′ may contain a pointer to block indicator information. The location register 120′ contains a first bit 130 indicative of the presence or absence of a mask register. When a mask is present, it follows the block selector in the location pointed to by the block indicator pointer 132. When the mask is not present, the block selectors that are pointed to are directly sequential. In a preferred embodiment, the control blocks pointed to reside in bank 0 of the port.

The control register 118, shown as 118 and 118′ in FIG. 3, may also contain direct control information or a pointer to control information. The control register 118 contains direct control information. In this case, a pointer indicator bit 140 indicates that the register does not contain a pointer. In some embodiments, the pointer indicator bit 140 indicates whether or not the control register 118 and the location register 120 contain pointers Accordingly, the pointer indicator bit 140 is a multiplex control for the control register 118 and the location register 120. The location register 120 need not have a dedicated bit for interpretation, and may rely on the pointer indicator bit 140 to specify whether or not the location register is a pointer. The pointer indicator bit 140 controls interpretation of registers 110. The control register 118 further contains an operational code 142 providing direction for handling operations on the designated block. This operational code 142 can include pointer handling, looping, and other operations. The operations also allow for non-contiguous blocks to be operated on using contiguous interface transactions. In some embodiments, a register field 144 contains the least three significant bits of the register address if the block contains an action on a single register within the block. In other embodiments, these least three significant bits are provided by the transaction protocol on the interface and serve to select the register in the block currently pointed to. The control register 118 further includes a port number 146. In some embodiments, the port number is included in the transaction protocol. However the port number 146 may specify an internal port address. This allows, for example, a device with a single external port address to support a plurality of internal port addresses. Further, port numbers may be provided that indicate groups of ports, or all ports in a device. This facilitates simplified programming on devices that have multiple ports. Accordingly, interface lines may grow beyond 32 ports. The 32 port restriction was based on the 5 bits used by a typical frame format. By providing indirect ports, the 5 direct bits may address clusters of ports, saving the direct bits to expand to a larger range. When other conventional systems reach the 32 port limit, additional management interfaces must be created. Embodiments of the present invention advantageously allow for addressing beyond the 32 port limit without the creation of the additional management interfaces.

The control register 118′ contains a pointer, as indicated by the pointer indicator bit 140, and a control pointer 150. As in the block indicator pointer 132 described above, the control pointer 150 points to information located in bank 0 of this port. There are 15 bits in the control pointer 150 and 16 bits of address space; both pointers indicate an even address where the least significant bit is zero without having it specified in the pointer. In other embodiments, the control register 160 and the location register 170 may reside in a bank other than 0 to allow control code to be shared among all ports in the device. This expanded pointer system accordingly allows simple flows for repeating operations. For example, in one embodiment a variety of physical layer statistics are read from disjoint locations. Once the control is setup, the interface can send enough read commands to get all the information. The op code 142 in the last block could loop back to the top in preparation for the next read cycle.

The control register 118′ points to one or more specified control registers 160. Each of these specified control registers 160 contain an operational code 142, a register field 144, and a port number 146. Each of these specified control registers 160 are then associated with specified location registers 170 pointed to by the block indicator pointer 132. Each of the specified location registers includes a bank selector 122 and a block selector 124. Further, if the mask indicator 130 indicates a mask, each of the specified location registers 170 are separated by a mask register 172.

In this manner, the addressing space of the vendor specific registers specified by the standard is expanded.

Through the use of a broadcast port, a plurality or all ports on a device can be setup in an identical manner through this stream. An example of this in a device containing n ports proceeds as follows. With the appropriate bank selector 122 and block selector 124, the associated port 146 would indicate a broadcast or group of port transaction. A write of information to a position in the selected block 112 would be replicated across the group or all ports on the device. This reduces the number of transactions by a quantity (number of register writes)*(n−1). Effectively, a single pass of the writes is used to cover all such ports. Use of the mask 172 and sequential operations allows for a fast setup of baseline parameters. This allows a faster setup through the serial interface. Usage of the mask registers 172 allows the setup to effect only certain bits in each register or block of registers.

In one embodiment, the control register 118′ and block register 120′, as well as registers 160 and 170 specified by these registers are located on a bank common to all ports of a system. This allows a common control and pointer group to be used over selected ports. The savings is that the control information only needs to be written once to cover operations common to a number of ports on the device.

Finally, grouping eight registers in a block, as shown in FIG. 2 with the block 112 allows those eight registers to be accessed without the need to adjust pointers. This allows a random access of each block for reads and writes. It also allows useful control and status to be grouped together for easier processing. By putting together control streams, larger blocks could be handled in other embodiments. Stream looping further allows large repetitive operations like collecting status and statistical counters to be performed more efficiently.

Accordingly, embodiments of the present invention provide for expansion of user register space beyond the finite amount specified by the standard. Access is allowed to other register banks inside the device. Cross-access to registers from different ports is allowed. Control streams may be provided for operations over several non-contiguous blocks. A larger information window is supported such that an indirect pointer can remain in the same position for several operations.

Further, the ability is provided to associate control blocks with various register blocks. The initial association of control and block pointers comes from 118′ and 120′, but the same control stream could operate on various block streams (variations in 132). The converse would also be true. One advantage is that with such a large amount of available registers, control streams can be setup for a variety of system flows, and remain resident in the actual device. This relieves some of the problems associated with a slow interface between the device and the system or in remote situations, a low bandwidth service channel.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. A method for expanding addressing capability of a plurality of registers connected to an interface comprising:
designating at least two of the plurality of registers as a block of registers;
providing a plurality of such blocks of registers;
designating a first register within the plurality of registers that is separate from the blocks of registers as a location register for selectively characterizing at least one of such blocks of registers as an indicated block of registers; and
designating a second register within the plurality of registers that is separate from the blocks of registers as a control register for specifying at least one operation for the indicated block of registers.

2. A method according to claim 1, wherein the first register includes a block selector for selectively characterizing at least one of such blocks of registers as an indicated block of registers.

3. A method according to claim 1, wherein the second register includes an operational code.

4. A method according to claim 3, wherein the second register includes a port indicator.

5. A method according to claim 1, wherein said first register comprises a pointer to a plurality of location registers, each indicating a register block and wherein said second register comprises a pointer to a plurality of control registers, each control register comprising an operational code, and wherein said plurality of location registers are associated with said plurality of control registers such that a first operational code is associated with a first block and a second operational code is associated with a second block.

6. A method according to claim 1, wherein said location and control registers comprise registers compatible with IEEE standard 802.3 clause 22.

7. A system for expanding the addressing capability of a plurality of registers, the system comprising:
a plurality of blocks of registers, each block of registers having at least two registers;
a location register separate from the plurality of blocks of registers for selectively characterizing at least one of the blocks of registers as a specified block of registers;
a control register separate from the plurality of blocks of registers for selecting at least one operational code for the specified block of registers and specifying at least one port number for the specified block of registers; and
a control engine operable to access the operational code for the specified block of registers and act on the specified block of registers at each of the specified port numbers in accordance with the operational code.

8. A system according to claim 7, wherein the operational code specifies an operation to be performed on the specified block of registers.

9. A system according to claim 8, wherein the operation is restricting the specified block of registers to read operations only.

10. A system according to claim 7, wherein the operational code specifies control sequencing information.

11. A system according to claim 10, wherein the control sequencing information instructs the control engine to proceed to a next block after completing operations with the specified block.

12. A system according to claim 7, wherein said location register includes a block selector indicating said block.

13. A system according to claim 7, wherein said location register includes a pointer to a block selector.

14. A system according to claim 7, wherein said location register includes a pointer to a plurality of registers, each including a block selector.

15. A system according to claim 7, wherein said control register is operable to store an operational code.

16. A system according to claim 15, wherein said control register is further operable to store a register indicator indicative of a register within said block.

17. A system according to claim 15, wherein said control register is further operable to store a port indicator.

18. A system according to claim 7, wherein said control register is operable to specify a plurality of ports.

19. A system according to claim 7, wherein said control register includes a pointer to a plurality of third registers, each having an operational code.

20. A system according to claim 7, wherein said location register includes a pointer to a plurality of location registers, each indicating a register block and wherein said control register includes a pointer to a plurality of control registers, each control register storing an operational code, and wherein said plurality of block indicator registers are associated with said plurality of control registers such that a first operational code is associated with a first block and a second operational code is associated with a second block.

21. A system according to claim 7, wherein said at least one operation is selected from the group of operations consisting of pointer handling and stream looping.

22. A system according to claim 7, wherein said lcoation and control registers are registers specified by IEEE standard 802.3 clause 22.

23. A system according to claim 7, further comprising:
a plurality of register banks, each bank including a plurality of register blocks.

24. A system according to claim 23, wherein said location register further indicates at least one of said register blocks.

25. A system according to claim 7 further comprising:
a mask register following the location register and specifying a mask for the specified block of registers.
